(19) United States
(12) Patent Application Publication
(10) Pub. No.: US 2008/0164862 A1
(43) Pub. Date: Jul. 10, 2008

(54) Method and Device For Determination of the Phases in a Multi-Phase Electrical System

(76) Inventors: Davide Tazzari, Arezzo (IT); Filippo Vernia, La Spezia (IT)

Correspondence Address: WADDEY & PATTERSON, P.C., 1600 DIVISION STREET, SUITE 500, NASHVILLE, TN, 37203, US

(21) Appl. No.: 11/909,018

(22) PCT Filed: Mar. 21, 2005
(86) PCT No.: PCT/IT2005/000149

§ 371 Date: Sep. 18, 2007

(51) Int. Cl. G01R 25/00

(52) U.S. Cl. 324/86

(57) ABSTRACT

To identify a phase in a multi-phase electrical system, the following method is proposed: transmission, on a defined phase (L1, L2, L3) of a line of the system, of a message with a known synchronization with respect to the phase voltage (V1, V2, V3); reception of the message on an undefined phase (X, Y, Z) of the line; identification of the phase on which the message has been received according to the displacement between the voltage on said undefined phase and the message received.

### TECHNICAL FIELD

The present invention concerns a so-called phase-finder device and a method for searching for a phase in a multi-phase electrical system, typically a three-phase system.

### BACKGROUND OF THE INVENTION

In electricity distribution systems in urban areas, interconnection lines connect the nodes of a complex network consisting of transformer stations, in which medium to low voltage transformers supply energy to the network, and junction or interconnection boxes, in which several lines are interconnected. The distribution system is three-phase and the distribution lines contain a plurality of cables for each phase. This is necessary due to the high current transmitted along the lines.

The cables of the various phases that form a line are often impossible to distinguish and are distributed in a disorderly fashion. Identifying which phase one of these cables belongs to is therefore a difficult and dangerous operation. In fact, work often has to be carried out on the lines while they are live.

Also in other situations, for example when connecting equipment to a three-phase line, it may be necessary to identify rapidly and safely the individual phases of an electrical supply system.

### OBJECTS AND SUMMARY OF THE INVENTION

The object of the present invention is to provide a method and a device that permit, simply and rapidly, identification of a phase in a multi-phase and in particular three-phase electrical supply system.

In principle, considering a three-phase distribution network, it would be possible to find a phase at a point of the distribution network by sending a message from a point in the network where the phases are known and recognizable.

In this case, assuming one single cable per phase is provided, a minimum of one to a maximum of three readings would have to be performed to identify on which of the three cables the message sent is propagated. This is the cable corresponding to the phase on which the message has been transmitted.

This method has serious limitations, however, and in practice cannot be implemented. Firstly, even in the simple case of one cable per phase, three different measurements may be necessary to establish which of the three cables belongs to the phase on which the control message has been sent. When there are several cables rather than one single cable for each phase, measurement can become very complex. If this measurement has to be performed without disconnecting the-power from the distribution network, it is not only a lengthy but also a very dangerous process.

Furthermore, in distribution networks with three-phase transformers, the message sent via carrier waves by a PLM on a phase is transmitted not only along that phase but also along the others. The transformer keeps the phases isolated at the network frequency, typically 50 or 60 Hz, but not at the PLM operating frequencies. The consequence of this is that a message sent on a phase L1, for example, is detected also on phase L2 or L3 of a three-phase system L1, L2, L3. This makes it impossible to distinguish between one phase and another.

In order to avoid these problems, the method according to the invention provides for the following:
applying a transmitter on a previously known phase at a point in the network and transmit, on this phase, a message synchronized with the phase voltage;
applying a receiver on any one of the phases at a different point in the network and receiving therewith the message on said phase;
obtaining information identifying the phase on which the message has been received according to the phase displacement between the voltage on said phase and the message received.

The method according to the invention is based on the fact that the phase voltages in the various phases of a three-phase electrical system are electrically displaced from each other by 120°. By sending a message via carrier waves and synchronizing it with one of the three phase voltages, it is possible to recognize on which phase the receiver is located by identifying the displacement between the message and the respective phase voltage.

According to a different aspect, the invention concerns a phase-finder device to determine the phase in a multi-phase electrical system, comprising: a transmitter, with terminals for connection to a phase of said multi-phase system, said transmitter comprising means for the transmission of a message on said phase and means for synchronization of the transmission with respect to the phase voltage; a receiver, with terminals for connection to a phase of said multi-phase system, said receiver comprising means to receive said message and to determine the displacement angle i.e. the delay or lead between the phase voltage to which the receiver is connected and the message received.

Further features and embodiments of the invention are indicated in the attached dependent claims and will be described in greater detail below with reference to an example of embodiment of the invention.

### BRIEF DESCRIPTION OF THE DRAWINGS

The invention will be better understood by following the description and the attached drawings, which illustrate a practical non-limiting embodiment of the invention. More in particular, in the drawing:

FIG. 1 shows schematically a portion of a three-phase electricity distribution network;

FIG. 2 shows the reciprocal displacement of the phase voltages in a vector representation;

FIG. 3 shows schematically a transmitter and a receiver of a device according to the invention;

FIG. 4 shows the phase voltage versus time and the synchronization thereof with a message transmitted by the transmitter;

FIG. 5 shows how the message is detected by a receiver connected to the same phase as the transmitter;

FIG. 6 shows how the message is detected by a receiver connected to a phase different from the phase to which the transmitter is connected;

FIGS. 7A, 7B, 7C show schematically the procedures for detecting an inversion of the connections between transmitter and receiver.

### DETAILED DESCRIPTION OF A PREFERRED EMBODIMENT OF THE INVENTION

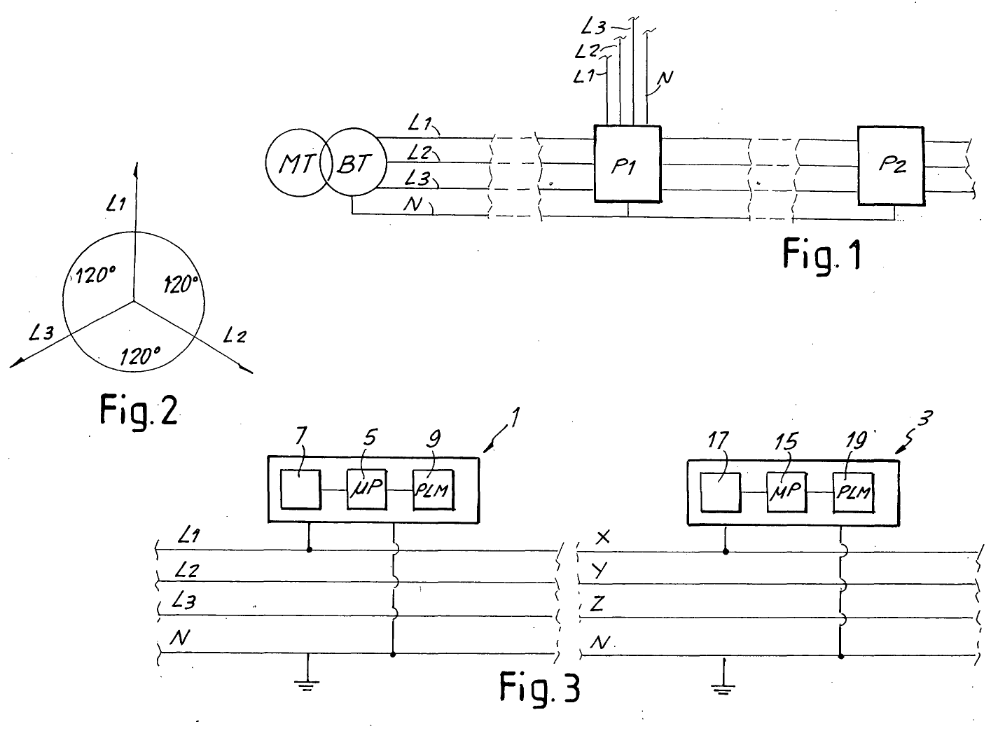

FIG. 1 schematically shows an MV/LV (medium voltage/low voltage) transformer which connects a medium voltage three-phase network to a low voltage three-phase network for the distribution of electricity. The low voltage three-phase network has three phases L1, L2, L3 and neutral N. The phase voltages are displaced by 120°, as shown in FIG. 2. The low voltage distribution network can also be very complex and present a plurality of junction or interconnection nodes or points. In the simplified diagram of FIG. 1 two interconnection or junction points P1 and P2 are shown. In practice these can consist of interconnection boxes, in which portions of distribution lines converge which must be interconnected. Each phase L1, L2, L3 at input and output of one of the interconnection points P1, P2 actually consists of a bundle of cables in an adequate number to withstand the maximum current to be delivered through that portion of distribution network.

In practice, protection ducts or tubes housing the cables of the various phases L1, L2, L3 and neutral N run between the transformer and the junction points adjacent to it, like point P1, in addition to between the various points or nodes P1, P2 etc. of the network. In an existing network, it is very difficult to distinguish the cables of one phase from those of another, since they do not usually feature any distinguishing characteristic. It is therefore very difficult to identify, for example at point P1, a cable belonging to phase L1, L2 or L3.

For said purpose, the invention provides for use of a transmitter device indicated overall by 1 in the diagram in FIG. 3 and a receiver device indicated overall by 3 in the same diagram. The device 1 comprises in general a pair of terminals or connections to connect the device between one phase (in the diagram in FIG. 3 phase LI) and the neutral N. Inside the device 1 a microprocessor schematically indicated by 5, a phase voltage zero crossing detector (block 7) and a PLM (Power Line Modem) 9 are provided. Connecting the device 1 to the phase and the neutral it is possible to detect the phase voltage versus time and its zero crossing and communicate via carrier waves with other devices connected to the network, for the purposes described herein.

The system according to the invention furthermore comprises a receiver device indicated overall by 11 in the diagram of FIG. 3, also comprising a microprocessor 15, a phase voltage zero crossing detector (block 17) and a PLM indicated by 19. The receiver 3, like the transmitter 1, can be connected to a phase and to the neutral N of the line. In practice the two devices 1 and 3 can be identical.

In the diagram of FIG. 3 the lines that represent the phases L1, L2, L3 are interrupted between the position in which the transmitter 1 is connected and the position in which the receiver 3 is connected, symbolically representing a considerable distance between these two positions. At the level of the receiver 3 the phases are indicated by X, Y and Z. This schematizes the fact that before the measurement it is not know how phases L1, L2 and L3 are arranged, i.e. it is not known which cables converging at node P1 belong to which one of the individual phases L1, L2 and L3. The receiver 3 is connected, therefore, between the neutral N and a general phase X, which could be any one of the phases L1, L2, L3.

In practice, the transmitter 1 is connected between a known phase, for example at the level of the MV/LV transformer, while the receiver 3 is connected to a point in the network, for example to the end of the cables which from the MV/LV transformer arrive at the first node P1 of the network.

By sending a message of known duration from the transmitter 1 along the phase L1 by means of carrier waves, the receiver 3 (receiving the message and determining the phase displacement with respect to the phase voltage) is able to identify the phase to which it is connected.

The message generated and transmitted by the transmitter 1 is propagated, along phase L1 (in the example in the drawing) and also along the cables of phases L2 and L3, due to the fact that at the frequency of the message (much higher than the frequency of the phase voltage) the transformer does not isolate the phases from each other.

The transmitter generates and transmits a message of pre-set length, i.e. the duration of which corresponds to a known electrical angle. Transmission of the message on the phase to which transmitter 1 is connected does not occur at random but begins at the moment when the phase voltage reaches a defined value. In this way the message is synchronized with respect to the phase voltage. Synchronization could occur with the peak value or with another value periodically reached by the phase voltage. Preferably, however, transmission of the message is synchronized with the phase voltage zero crossing. For said purpose the voltage zero crossing detector is provided in the transmitter 1.

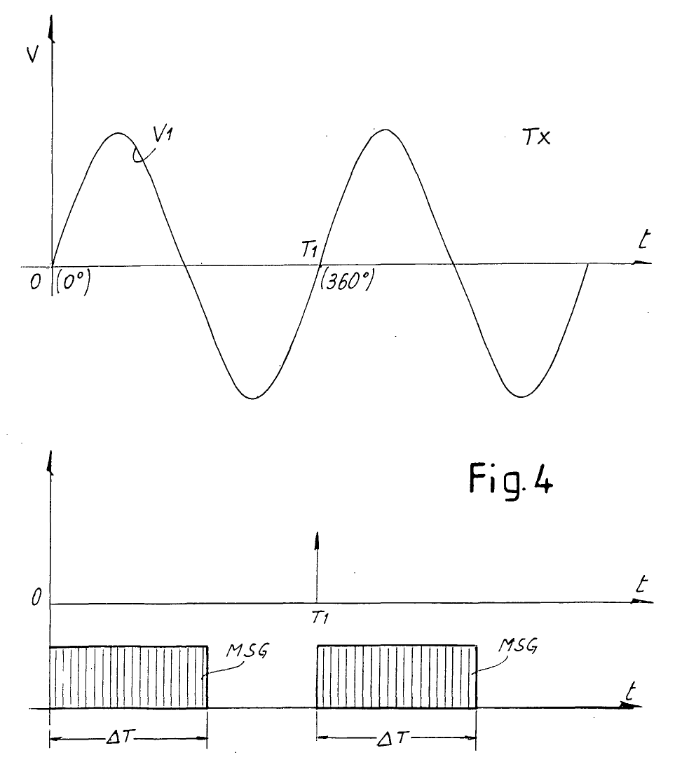

In practice, the message is transmitted as schematized in FIG. 4. This figure shows the phase voltage V1 versus time on the phase L1. At the moment 0 and at the moment T1 (corresponding to an electrical angle of 0° and 360° respectively) the increasing voltage V1 passes through zero. The microprocessor 5 transmits the message MSG with duration ΔT as from the moment T=0 and T=T1. The message MSG is therefore synchronized with respect to the phase voltage V1.

Said message is propagated on phase L1 and, as said previously, on phases L2 and L3. However the time position (i.e. the phase displacement) of the message with respect to the phase voltage on phases L2 and L3 will not be the same as on phase L1.

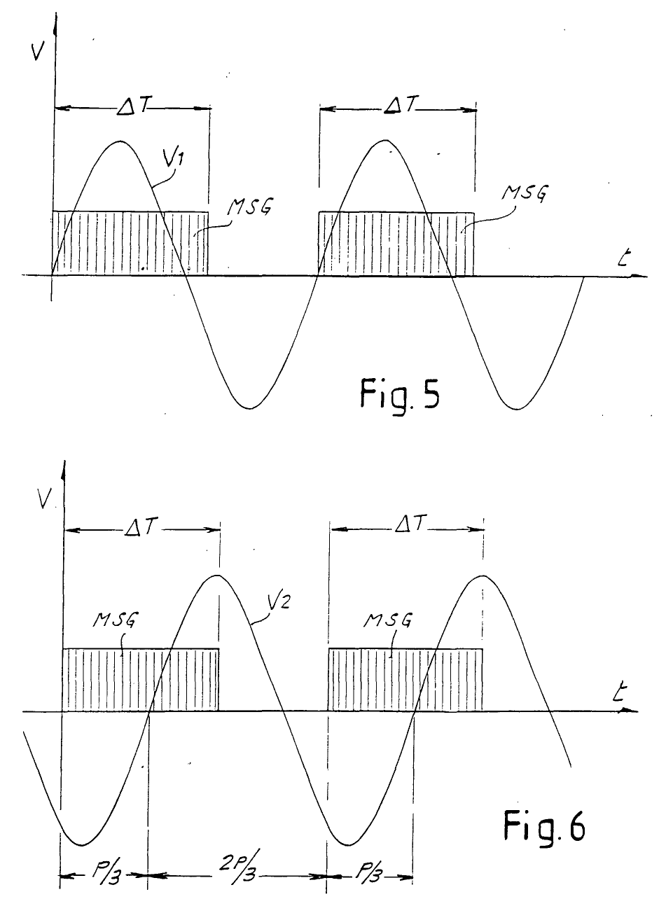

FIG. 5 shows schematically the voltage V1 which the receiver RX detects if connected to phase V1. The receiver also receives the message MSG in phase with the voltage V1, i.e. in phase with the zero crossing of said voltage. The diagram shows as an example two periods of the voltage V1 and two messages MSG. The time length, i.e. the duration ΔT of the message, can be different from the one indicated in proportion to the period of the waveform V1.

The message MSG will have an initial portion that identifies the beginning of the message and a final validation code. The microprocessor 15 of the receiver 3 will recognize and validate the message MSG only after it has been fully received and therefore after a time ΔT from the beginning of the reception. The time count is performed as from the zero crossing of V1. Validation of the message, i.e. its recognition as a valid message, will therefore occur in this case with a time displacement ΔT with respect to the zero crossing of the voltage V1, detected by the detector 17. To this time displacement corresponds a displacement in terms of electrical angle which depends on the network frequency.

Therefore, the microprocessor 15 of the receiver 3 is able to recognize the phase to which it is connected as phase L1 when the displacement between the zero crossing of the phase voltage V1 and the end of the message is equal to the duration ΔT of the message itself (or the electrical angle corresponding to said time duration).

If the phase X to which the receiver 3 is connected is phase L2, which is displaced. by a delay of 120° with respect to phase L1, the displacement between the end of the message MSG and the phase voltage, detected by the receiver 3, would be the one shown in FIG. 6, equal to ΔT+P/3, where P is the period of oscillation of the voltage.

If the phase X to which the receiver 3 is connected is phase L3, the displacement between the end of the message MSG and the zero crossing of the phase voltage would be equal to ΔT+2P/3.

Therefore, simply transmitting the message MSG on one of the phases L1, L2, L3 and, receiving said message on an unknown phase (which must be identified and recognized via the receiver 3) on the basis of measurement of the displacement between the tail of the message MSG and the zero crossing of the phase voltage, the receiver 3 is able to determine to which phase it is connected. This naturally presupposes that the message MSG can be propagated on all the phases L1, L2, L3 up to the position where the receiver 3 is located.

If it is necessary for example to combine with each node or point P1, P2 etc. of the network a device that is always connected to the same phase L1 of the three-phase network, the following procedure can be performed. The transmitter 1 is applied to the phase L1 at the level of the MV/LV transformer. The receiver 3 is connected to an unknown phase in point P1. The detection procedure as described above is performed via transmission of the message from the PLM 9 of the transmitter 1 to the PLM 19 of the receiver. In this case the measurement can be repeated more than once connecting the receiver to cables which are always different, until phase X to which the receiver 3 has been connected is phase L1.

At this point the receiver 3 is left at the point where it was applied and the transmitter is connected to an unknown phase in point P2. The procedure is repeated. In practice, receiver 3 and transmitter 1 can be identical to each other and can both transmit/receive the same message on the line.

When it is sufficient to identify to which of the phases L1, L2, L3 the unknown phase X to which the receiver 3 is connected corresponds, the measuring process is performed only once.

The above description assumes that the neutral N can be distinguished from the cables of the phases L1, L2, L3. In this case the voltage read by the receiver 3 is the phase voltage with respect to the neutral. However, the system operates also if the neutral cable cannot be distinguished from the others and therefore also if the connection of the receiver 3 is made with a further degree of uncertainty.

In this case, in fact, the detection can be performed in two stages, for example. In the first stage the receiver 3 is connected between any two cables and a voltmeter (if necessary incorporated in the same receiver) reads the voltage between the terminals. If this is zero, it means that the cables chosen belong to the same phase or to the neutral. If the voltage is equal to the phase-phase voltage, modify the connection until the voltage detected is the one between phase and neutral. Then proceed as described above to identify which of the three phases L1, L2, L3 has been engaged by the receiver.

Alternatively, the measurement can be performed even if the connection is made between two phases instead of between phase and neutral. In this case, with respect to the voltage on phase L1, the voltage will have its own displacement which depends on which of the two phases have been engaged by the receiver and in which of the two possible configurations (for example phases L1, L2 to terminals A and B or phases L1, L2 to terminals B and A respectively). Detection of the zero crossing of the phase-phase voltage and detection of the delay as described above still permit identification of which phases are connected to the receiver and in which position.

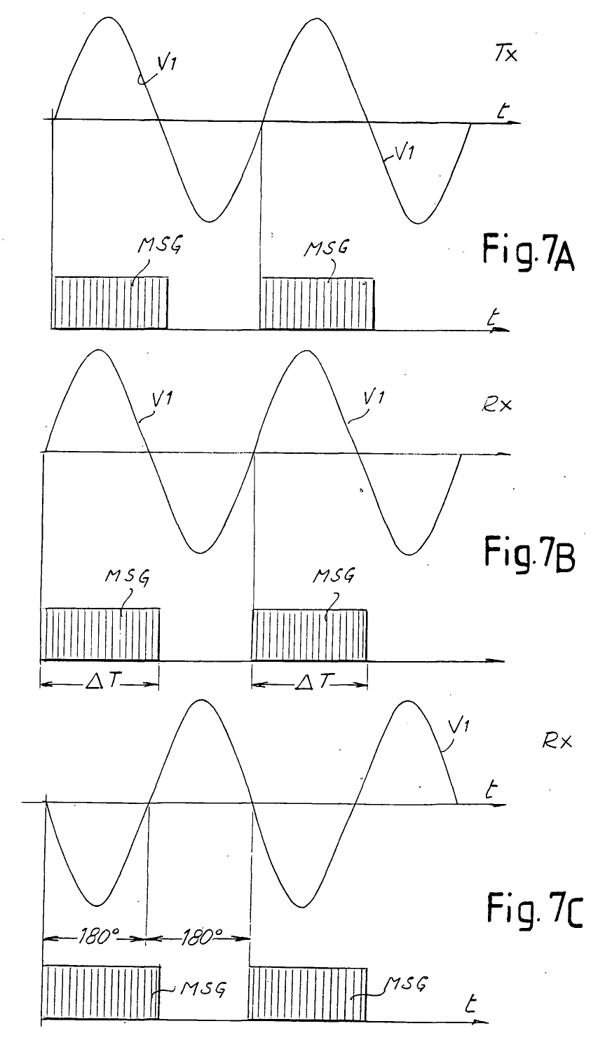

The system described is also able to recognize if on the receiver the phase and the neutral are connected inverted with respect to the connection on the transmitter. This situation is detected via a 180° phase shift of the message. FIGS. 7A, 7B, 7C illustrate this possibility. FIG. 7A shows the phase voltage V1 versus time seen by the transmitter and the message MSG transmitted by the. transmitter in phase with the zero crossing. FIG. 7B shows the message MSG detected, in phase with the phase voltage V1, by a receiver RX connected on the same phase as the transmitter and with correct arrangement between phase and neutral. FIG. 7C, on the other hand, shows. the waveform and the MSG message detected by the receiver when it is connected with phase and neutral inverted. A displacement of 180° is detected between message and line voltage, a symptom of incorrect connection of the cables on the receiver.

The drawing obviously only shows one practical embodiment of the invention, which can vary in the forms and arrangements without departing from the scope of the concept underlying the invention. The possible presence of reference numbers in the attached claims has the sole purpose of facilitating reading thereof in the light of the preceding description and the attached drawings and does not in any way limit the protective scope thereof.

1-13. (canceled)

14. A method for identifying a phase in a multi-phase electrical system, including:
transmitting, on a defined phase of a line of the system, a message with a known synchronization with respect to a phase voltage;
receiving the message on an undefined phase of the line;
obtaining information on the phase on which the message is received according to a phase displacement between a voltage on said undefined phase and the message received.

15. The method of claim 14, wherein the phase on which the message has been received is identified according to said phase displacement.

16. The method of claim 14, wherein said multi-phase system is a three-phase system.

17. The method of claim 15, wherein said multi-phase system is a three-phase system.

18. The method of claim 14 wherein said message is transmitted in synchronism with a zero crossing of the phase voltage on said defined phase.

19. The method of claim 15, wherein said message is transmitted in synchronism with a zero crossing of the phase voltage on said defined phase.

20. The method of claim 14 further comprising:
transmitting a message of known length on said defined phase of the multi-phase system, with a pre-defined synchronization with respect to the phase voltage;
receiving said message on an undefined phase of the multi-phase system;
determining a phase displacement between the end of the message received and the phase voltage on said undefined phase;
identifying, according to the length of the message and said phase displacement, the phase on which the message has been received.

21. The method of claim 14 further comprising:
coupling a transmitter to said defined phase at a first point of a distribution network of said multi-phase system;
coupling a receiver to an undefined phase at a different point of the distribution network;
using said transmitter, transmitting said message in synchronism with the phase voltage of said known phase;
receiving said message via said receiver, determining the phase displacement between the message and the phase voltage on said undefined phase;
identifying the phase on which the message has been received according to said phase displacement.

22. The method of claim 21, wherein said transmitter and said receiver are each connected between a phase and the neutral and said phase displacement determines whether the receiver is connected in phase or in opposition.

23. A device to determine a phase in a multi-phase electrical system comprising:
a transmitter, with terminals for electrical connection to a phase of said multi-phase system, said transmitter functional to transmit a message by carrier waves on said phase and to synchronize transmission of the message with respect a phase voltage;
a receiver, with terminals for electrical connection to a phase of said multiphase system, said receiver functional to receive said message and to determine a phase displacement between a phase voltage on the phase to which the receiver is coupled and the message received.

24. The device of claim 23, further including a control unit which, according to said phase displacement, determines the phase to which the receiver is electrically connected.

25. The device of claim 23, wherein said transmitter and said receiver each comprise a microprocessors.

26. The device of claim 24, wherein said transmitter and said receiver each comprise a microprocessor.

27. The device of claim 23, wherein said transmitter and said receiver each comprise a power line modem for transmission and reception of said message.

28. The device of claim 24, wherein said transmitter and said receiver each comprise a power line modem for transmission and reception of said message.

29. The device of claim 23, wherein said transmitter and said receiver each comprise a phase voltage zero crossing detector.

30. The device of claim 23 wherein said transmitter and said receiver are identical, and wherein said transmitter and receiver are each is operable
to transmit and receive messages,
to synchronize transmission of messages with respect to a phase voltage, and
to determine a phase displacement between the phase voltage and the message.
